(19) United States
(12) Patent Application Publication
(10) Pub. No.: US 2014/0347063 A1
(43) Pub. Date: Nov. 27, 2014

(54) FAN TEST DEVICE

(71) Applicants: HONG FU JIN PRECISION INDUSTRY (Shenzhen) CO., LTD, Shenzhen (CN); HON HAI PRECISION INDUSTRY CO., LTD., New Taipei (TW)

(72) Inventors: BO TIAN, Shenzhen (CN); KANG WU, Shenzhen (CN)

(73) Assignees: HONG FU JIN PRECISION INDUSTRY (Shenzhen) CO., LTD, Shenzhen (CN); HON HAI PRECISION INDUSTRY CO., LTD., New Taipei (TW)

(21) Appl. No.: 14/282,014

(22) Filed: May 20, 2014

(30) Foreign Application Priority Data
May 24, 2013 (CN) 2013101982188

(51) Int. Cl. G01R 31/02

(52) U.S. Cl. CPC G01R 31/02
USPC 324/511

(57) ABSTRACT

A fan test device to connect a motherboard and a fan includes a power terminal, a first diode, a second diode, a control chip, a first connector, a second connector, a first electronic switch and a second electronic switch. The control chip is connected to signal pins and sensing pins of the first and second connectors. The first electronic switch is connected between the control chip and a power pin of the first connector. The second electronic switch is connected between the control chip and a power pin of the second connector. The control chip outputs different signals corresponding to the connection of the first and second connectors.

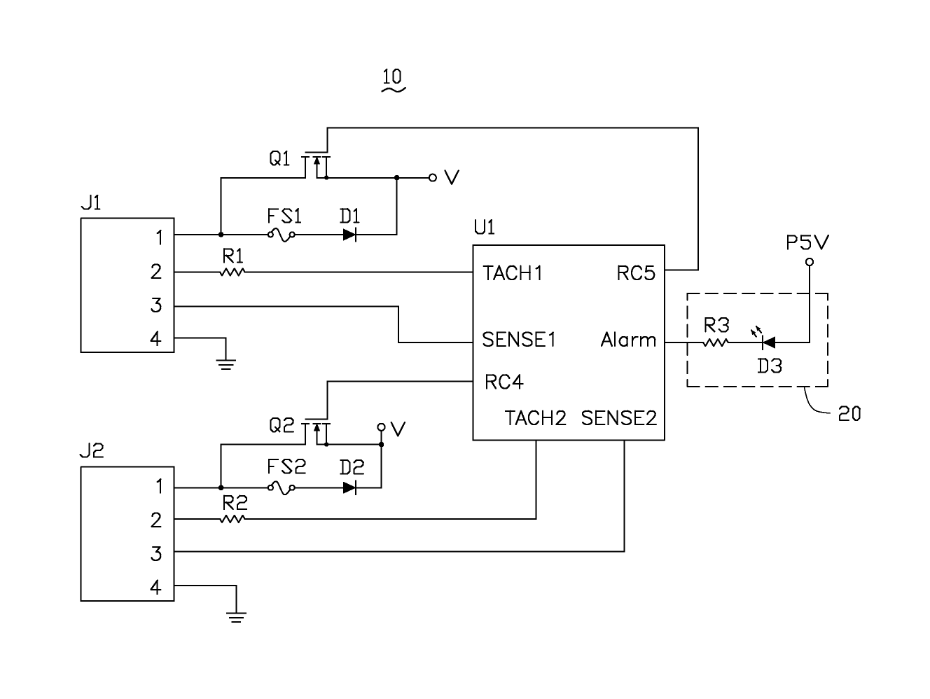

### FIELD

The present disclosure relates to a fan test device.

### BACKGROUND

Typically, a fan test device has a first connector to connect to a motherboard and a second connector to connect a fan. The first and second connectors look similar to each other which may cause confusion. The fan test device may be damaged when the connections are incorrect.

### BRIEF DESCRIPTION OF THE DRAWING

Many aspects of the present disclosure can be better understood with reference to the following drawing. The components in the drawing are not necessarily drawn to scale, the emphasis instead being placed upon clearly illustrating the principles of the present disclosure.

The FIGURE is a circuit diagram of an embodiment of a fan test device of the present disclosure.

### DETAILED DESCRIPTION

The disclosure is illustrated by way of example and not by way of limitation in the figures of the accompanying drawings in which like reference numerals indicate similar elements. It should be noted that references to “an” or “one” embodiment in this disclosure are not necessarily to the same embodiment, and such references mean “at least one.” The reference “a plurality of” means “at least two.”

The FIGURE shows an embodiment of a fan test device 10 of the present disclosure.

The fan test device 10 can comprise a first connector J1, a second connector J2, a first electronic switch Q1, a second electronic switch Q2, a control chip U1, a resistor R1, a resistor R2, a diode D1, a diode D2, an alarm module 20, a first power terminal V, a fuse FS1, and a fuse FS2.

As illustrated, a first terminal of the first electronic switch Q1 can be connected to a control pin RC5 of the control chip U1. A power pin 1 of the first connector J1 is connected to a second terminal of the first electronic switch Q1. A third terminal of the first electronic switch Q1 is connected to a cathode of the diode D1. An anode of the diode D1 is coupled to the power pin 1 of the first connector J1 through the fuse FS1. A signal pin 2 of the first connector J1 is coupled to a signal pin TACH1 of the control chip U1 through the resistor R1. A sensing pin 3 of the first connector J1 is connected to a sensing pin SENSE1 of the control chip U1. A ground pin 4 of the first connector J1 is grounded.

A first terminal of the second electronic switch Q2 is connected to a control pin RC4 of the control chip U1. A power pin 1 of the second connector J2 is connected to a second terminal of the second electronic switch Q2. A third terminal of the second electronic switch Q2 is connected to the first power terminal V. The third terminal of the second electronic switch Q2 is also connected to a cathode of the diode D2. An anode of the diode D2 is coupled to the power pin 1 of the connector J2 through the fuse FS2. A signal pin 2 of the second connector J2 is coupled to a signal pin TACH2 of the control chip through the resistor R2. A sensing pin 3 of the second connector J2 is connected to a sensing pin SENSE2 of the control chip U1. A ground pin 4 of the second connector J2 is grounded. The fuse FS1 and the fuse FS2 are used to prevent damage from excess current.

When the first connector J1 is connected to a motherboard and the second connector J2 is connected to a fan, the motherboard outputs a first signal to the sensing pin SENSE1 of the control chip U1 through the sensing pin 3 of the first connector J1. The control chip U1 outputs a low level signal, such as logic 0, to the first terminal of the first electronic switch Q1. The first electronic switch Q1 is turned off. A voltage from the motherboard is output to the first power terminal V through the power pin 1 of the first connector J1, the fuse FS1, the anode of the diode D1, and the cathode of the diode D1 in that order. The fan outputs a second signal to the sensing pin SENSE2 of the control chip U1 through the sensing pin 3 of the second connector J2. The control chip U2 outputs a high level signal, such as logic 1, to the first terminal of the second electronic switch Q2 through the control pin RC4. The second electronic switch Q2 is turned on. The voltage from the motherboard is input to the power pin 1 of the second connector J2 through the first power terminal V. Thus, the motherboard supplies power to the fan. The control chip U1 receives a third signal of a speed of the fan through the signal pin 2 of the second connector J2 and the signal pin TACH2. The control chip U1 outputs the third signal to the motherboard through the signal pin TACH1 and the signal pin 2 of the first connector J1 when the control chip U1 determines that the speed of the fan is abnormal.

When the first connector J1 is connected to the fan and the second connector J2 is connected to the motherboard, the motherboard outputs the first signal to the sensing pin SENSE1 of the control chip U1 through the sensing pin 3 of the second connector J2. The control chip U1 outputs a low level signal to the first terminal of the second electronic switch Q2. The second electronic switch Q2 is turned off. The motherboard outputs the voltage to the first power terminal V through the power pin 1 of the second connector J2, the fuse FS2, the anode of the diode D2, and the cathode of the diode D2 in that order. The fan outputs the second signal to the sensing pin SENSE1 of the control chip U1. The control chip U1 outputs a high level signal to the first terminal of the first electronic switch Q1. The first electronic switch Q1 is turned on. The motherboard supplies power to the fan. The control chip U1 receives the third signal through the signal pin 2 of the first connector J1 and the signal pin TACH1. The control chip U1 outputs the third signal to the motherboard through the signal pin TACH2 and the signal pin 2 of the second connector J2 when the control chip U1 determines that the speed of the fan is abnormal.

The alarm module 20 comprises a resistor R3 and a light emitting diode (LED) D3. An anode of the LED D3 is connected to a second power terminal P5V. The second power terminal P5V is used to input a high level signal. In the embodiment, the second power terminal P5V is connected to the first power terminal V. When the control chip U1 determines that the speed of the fan is abnormal, the control chip U1 outputs a low level signal through the alarm pin Alarm. When the control chip U1 determines that the speed of the fan is normal, the control chip U1 outputs a high level signal through the alarm pin Alarm.

In the embodiment, the first and second electronic switches Q1 and Q2 are both n-channel filed effect transistors (FETs).

The fan test device operates normally either when the first connector J1 is connected to the motherboard and the second connector J2 is connected to the fan or when the first connector J1 is connected to the fan and the second connector J2 is connected to the motherboard.

While the disclosure has been described by way of example and in terms of preferred embodiment, it is to be understood that the disclosure is not limited thereto. To the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A fan test device connectable between a motherboard and a fan, the fan test device comprising:
a first power terminal to receive a voltage from the motherboard and output the voltage to the fan;
a first diode and a second diode;
a first connector and a second connector;
a control chip, wherein a first signal pin of the control chip is connected to a signal pin of the first connector, a first sensing pin of the control chip is connected to a sensing pin of the first connector, a second signal pin of the control chip is connected to a signal pin of the second connector, s second sensing pin of the control chip is connected to a sensing pin of the second connector, the control chip receives signals from the motherboard and the fan through the first and second sensing pins and outputs signals through a first control pin and a second control pin correspondingly; and
a first electronic switch and a second electronic switch, wherein a first terminal of the first electronic switch is connected to the first control pin of the control chip, a second terminal of the first electronic switch is connected to a power pin of the first connector, a third terminal of the first electronic switch is connected to a cathode of the first diode, an anode of the first diode is connected to the power pin of the first connector, a first terminal of the second electronic switch is connected to the second control pin of the control chip, a second terminal of the second electronic switch is connected to a power pin of the second connector, a third terminal of the second electronic switch is connected to a cathode of the second diode, the third terminal is also connected to the first power terminal, an anode of the second diode is connected to the power pin of the second connector, and the first and second electronic switches are activated when the first terminals are at high level, and deactivated when the first terminals are at low level.

2. The fan test device of claim 1, further comprising an alarm module, wherein the alarm module is connected to an alarm pin of the control chip, and the control chip outputs an alarm signal to the alarm module when the control chip determines a speed of the fan is abnormal.

3. The fan test device of claim 1, wherein the first and the second electronic switches are n-channel field effect transistors.

4. The fan test device of claim 2, wherein the alarm module further comprises a first resistor and a light emit diode (LED), an anode of the LED is connected to a second power terminal, and a cathode of the LED is connected to the alarm pin of the control pin through the first resistor.

5. The fan test device of claim 1, further comprising a first fuse and a second fuse, the first fuse is connected between the power pin of the first connector and the anode of the first diode, and the second fuse is connected between the power pin of the second connector and the anode of the second diode.

6. The fan test device of claim 1, further comprising a second resistor and a third resistor, the second resistor is connected between the signal pin of the first connector and the first signal pin of the control chip, and the third resistor is connected between the signal pin of the second connector and the second signal pin of the control chip.
